(19) United States
(12) Patent Application Publication
(10) Pub. No.: US 2006/0125090 A1
(43) Pub. Date: Jun. 15, 2006

(54) Heat dissipation structure and method thereof

(75) Inventors: Hsuch-Chung Chen, Yonghe City (TW); Yi-Lung Cheng, Danshuei Township (TW); Hsien-Wei Chen, Shinying City (TW); Shin-Puu Jeng, Hsinchu City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Taiwan Semiconductor Manufacturing Co., Ltd.

(21) Appl. No.: 11/338,551

(22) Filed: Jan. 24, 2006

Related U.S. Application Data
(63) Continuation of application No. 10/829,583, filed on Apr. 22, 2004.

(51) Int. Cl. H01L 23/34

(52) U.S. Cl. 257/712

(57) ABSTRACT

A semiconductor structure and method for dissipating heat away from a semiconductor device having a plurality of power lines is provided. The semiconductor structure includes a semiconductor substrate and a plurality of interconnect structures disposed on the substrate and in contact therewith and extending through the semiconductor device, the interconnect structures for dissipating heat to the substrate. Each of the plurality of interconnect structures comprises at least one via stack.

### BACKGROUND

The present invention relates generally to semiconductor device structures, and more particularly, to semiconductor device structures having improved heat dissipation capabilities.

Due to the continuing scaling of device features and the demands for higher processing speeds, integrated circuits consume more and more power and generate more heat. This heat must be dissipated in order to maintain acceptable operating temperatures and avoid reliability problems in integrated circuits. This is especially problematic in the area of metallization where metal layers are sandwiched between insulating materials on a substrate. The traditionally used insulating material is silicon dioxide (SiO), having a dielectric constant (k) of approximately four. However, it is known that better device performance may be realized by replacing silicon dioxide with low dielectric constant (“low-k”) materials which reduce the capacitance of the device thereby increasing device speed. One drawback, however, is that most low-k materials have poor thermal conductivity (at about 3-30 times lower thermal conductivity than silicon dioxide) which lead to heat build-up and poor reliability in integrated circuits.

In view of this, various methods have been proposed to provide heat dissipation to semiconductor devices. One such method is attaching heat sinks to the backside of a die or a pc board. Another is by blowing air using cooling fans. However, such methods address the heat dissipation for the device package and therefore may not be particularly suitable or efficient in conducting heat away from the device itself. Moreover, heat dissipation within the device has not hitherto been fully addressed.

Accordingly, what is needed in the art is a structure and method for forming a semiconductor structure with improved heat dissipation.

### SUMMARY

The present invention is directed to semiconductor structures for dissipating heat away from a semiconductor device having a plurality of power lines. In one embodiment, the semiconductor structure includes a semiconductor substrate and a plurality of interconnect structures disposed on the substrate and in contact therewith and extending through the semiconductor device, the interconnect structures for dissipating heat to the substrate. Each of the plurality of interconnect structures includes at least a via stack. In one embodiment, the interconnect structures are closed to a power line. In another embodiment, the interconnect structures are disposed within a power bus line, the plurality of interconnect structures are substantially enveloped in a dielectric film. Methods for forming a semiconductor structure for dissipating heat away from a semiconductor device having a plurality of power lines are also provided. In one embodiment, a semiconductor substrate is provided; and a plurality of interconnect structures is formed disposed on the substrate and in contact therewith and extending through the semiconductor device, the interconnect structures for dissipating heat through the substrate.

### BRIEF DESCRIPTION OF THE DRAWINGS

The features, aspects, and advantages of the present invention will become more fully apparent from the following detailed description, appended claims, and accompanying drawings in which:

FIG. 1 shows a cross sectional view of a semiconductor structure for heat dissipation in a semiconductor device according to one embodiment of the present invention.

FIG. 2 shows a top view of the semiconductor structure of FIG. 1.

FIG. 3 shows a cross sectional view of a semiconductor structure for heat dissipation in a semiconductor device according to another embodiment of the present invention.

FIG. 4 shows a top view of the semiconductor structure of FIG. 3.

FIG. 5 shows a cross sectional view of a semiconductor structure for heat dissipation in a semiconductor device according to yet another embodiment of the present invention.

FIG. 6 shows a top view of the semiconductor structure of FIG. 5.

### DETAILED DESCRIPTION

In the following description, numerous specific details are set forth to provide a thorough understanding of the present invention. However, one having an ordinary skill in the art will recognize that the invention can be practiced without these specific details. In some instances, well-known structures and processes have not been shown in detail to avoid unnecessarily obscuring the present invention. Furthermore, it is understood that the description provides many different embodiments, or examples, for implementing different features of the invention. Also, the description may repeat reference numerals and/or letters in the various examples. This repetition is for the purpose of simplicity and clarity and does not in itself dictate a relationship between the various embodiments and/or configurations discussed.

Reference will now be made in detail to the present exemplary embodiments of the present invention, which are illustrated in the accompanying drawings.

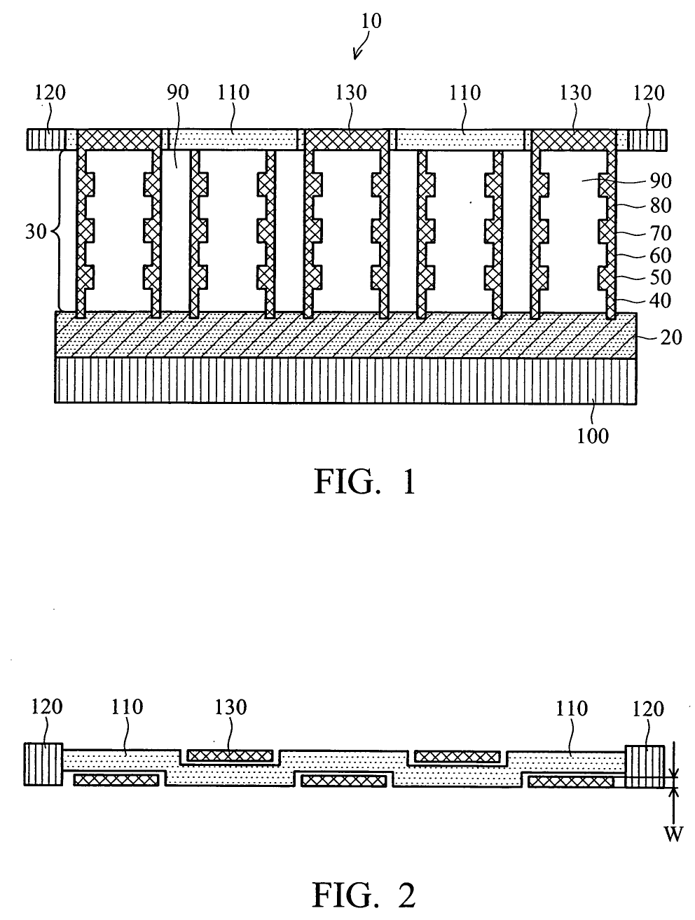

Typically, heat produced in a semiconductor device simply flows out through materials utilized to form the basic wiring structure within the semiconductor device. Often, no special structures are provided to help dissipate heat within the semiconductor device. FIG. 1 shows a cross sectional view of a semiconductor structure for heat dissipation in a semiconductor device according to one embodiment of the present invention. A semiconductor structure 10 includes a semiconductor substrate 20 and a plurality of interconnect structures disposed on substrate 20 and in contact therewith. Substrate 20 may include active and passive devices formed therein and vias, contacts, conductive layers, and dielectric layers (e.g. interlayer dielectric (ILD)) formed thereabove. It will be understood that various conventional materials such as silicon (Si) and germanium (Ge) and future-developed semiconductor materials may be used for substrate 20. Unless otherwise specified, all structures, layers, etc. may be formed or accomplished by conventional methods as is known to those skilled in the art.

The plurality of interconnect structures in semiconductor structure 10 are not part of the active circuitry but serve to improve the heat dissipation of the semiconductor device. Each of the plurality of interconnect structures includes at least a via stack 30. Via stack 30 may include a contact 40, patterned metal layer 1 (50), via 1 (60), patterned metal layer 2 (70), via 2 (80), and so on, extending up to a top patterned metal layer n and may be formed by conventional lithography, metallization and etching processes as is known to those skilled in the art. Via stacks 30 are formed on substrate 20 with insulating material 90 separating each via stack 30. Insulating material 90 includes multilayers of interlayer dielectrics that once deposited, are patterned and etched to form via openings for the various patterned metal layers on substrate 20. A metal plug such as tungsten (W), aluminum (Al), copper (Cu) or other conductive material fills the vias to form the electrical connection (interconnect) between any two patterned metal layers. The filled via openings are usually for providing electrical connections between metal layers, but in the present invention they are useful for providing a thermal pathway to substrate 20. This structure of vias and patterned metal layers which can be built further upward in a repeated structural sequence comprises via stack 30. The construction and structure of via stacks 30 should be the same as the construction and structure of passive (e.g. metal layers) and/or active components of a device and may be formed at the same time that passive and/or active components are formed. To simplify fabrication of the plurality of via stacks 30, the same are preferably made from the same material as conventional interconnect structures.

Insulating material 90 may include the ubiquitous insulating material silicon dioxide (SiO), having a dielectric constant (k) of approximately four. However, better device performance may be realized by replacing silicon dioxide with low dielectric constant (“low-k”) materials such as, for example organic polymer, silicon carbide, silicon oxide glass, fluorinated silicon dioxide, foamed polymer, and the like which reduce the capacitance of the device thus increasing device speed. One shortcoming of low-k material, however, is that most of these materials exhibit poor heat dissipation compared to silicon dioxide. Moreover, the dielectric constant of low-k materials is proportional to the thermal conductivity. That is, the lower the dielectric constant, the poorer the thermal conductivity. Thus, heat generated in the device structure during operation is more difficult to remove leading to poor device performance.

For this reason and the reason that substrate 20 serves as an effective heat sink and the plurality of via stacks 30 serve as good thermal paths for conducting heat away from the semiconductor device, via stacks 30 have one end in contact with substrate 20. In another embodiment, via stacks 30 may be connected to ground. Optionally, substrate 20 may be connected to a heat sink 100 for increased heat dissipation ability. The other end, or the top end of via stack 30 may be disposed near a metal line 110, such as a power line so that via stack 30 may conduct the heat generated by power line 110 into substrate 20 through the plurality of via stacks 30. It is understood that the top end of via stack 30 is not in contact with power line 110 to avoid an electrical short. Power line 110 may be aluminum, copper, tungsten, or other conductive material, preferably a metal, and is connected to bond pads 120 on either side. Via stacks 30 may be used in a multi-level interconnect semiconductor device, in various patterned metal layers, such as a top patterned metal layer. In one embodiment, the top end of via stack 30 is a top patterned metal layer of via stack 30. In another embodiment, the top end of via stack 30 is any patterned metal layer other than the top patterned metal layer of via stack 30.

Semiconductor structure 10 shown in FIG. 1, depicts at least one of the plurality of via stacks 30 joined to one other via stack 30 via a patterned metal layer to form a bridged via stack structure 130. The bridged via stack structures 130 are shown spaced apart alternatively from each other from a serpentine power line 110. A top view of the semiconductor structure of FIG. 1 depicting the serpentine power line 110 and the bridged via stack structures 130 alternatively spaced apart from each other is shown in FIG. 2. In one embodiment, a width W of bridged via stack structure 130 is from about 0.1 μm to about 10 μm, although this may be further reduced as process technology improves; and the distance that a bridged via stack structure 130 is spaced apart from another bridged via stack structure 130 is a width of one bridged via stack structure 130. In general, however, the dimensions of bridged via stack structure 130 are limited by the device technology. In another embodiment, the distance that a bridged via stack structure 130 is spaced apart from power line 110 is the width of one bridged via stack structure 130. However, it is understood by those skilled in the art that the placement and the number of bridged via stack structures 130 disposed about power line 110 as well as the dimensions of bridged via stack structures 130 are determined based upon the circuit pattern, the design rules for integrated circuit device being fabricated, and heat dissipation concerns for efficiently dissipating heat away from the semiconductor device. It is further understood that the dimensions of bridged via stack structures 130 may be further reduced as process technology improves.

In another embodiment, the bridged via stack structures 130 may be disposed on only one side of a serpentine power line 110. In yet another embodiment, the bridged via stack structures 130 may be spaced apart alternatively from each other from a straight power line 110.

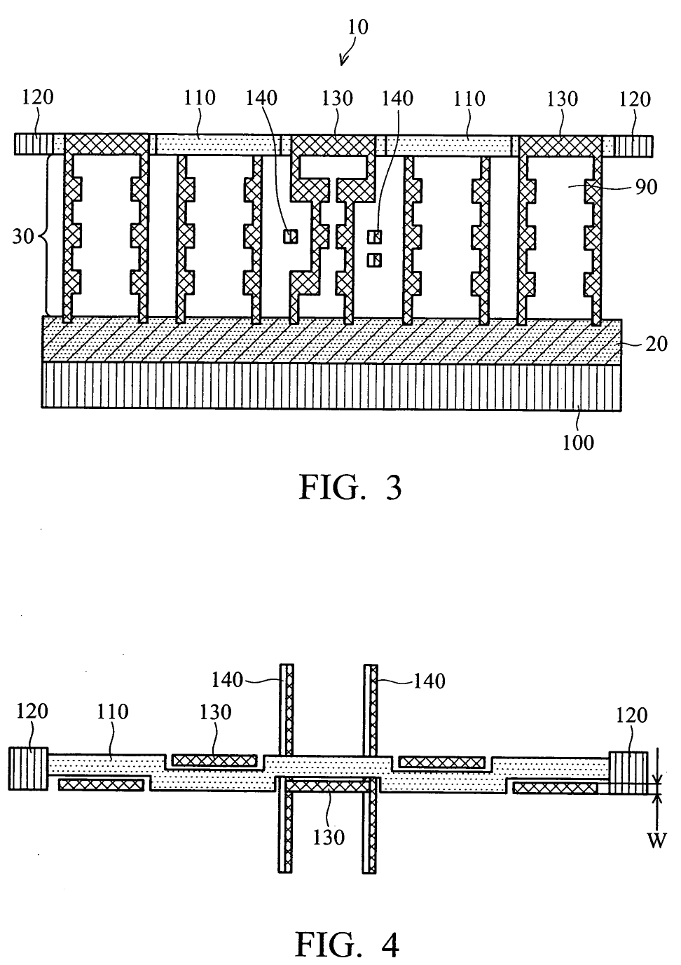

Bridged via stack structures 130 may be arranged in a variety of configurations in insulating material 90 and any number of them may be used depending on the particular application, circuit pattern and design rule considerations as would be understood by those skilled in the art. FIG. 3 shows a cross-sectional view of semiconductor structure 10 having bridged via stack structures 130 arranged in insulating material 90 bypassing or going around interconnects 140. It is understood that bridged via stack structures 130 are disposed near interconnects 140 to conduct the heat generated by interconnects 140 into substrate 20 through bridged via stack structures 130 and further that bridged via stack structures 130 are not in contact with interconnects 140 to avoid an electrical short. FIG. 4 shows a top view of semiconductor structure 10 of FIG. 3. The configuration of bridged via stack structures 130 shown in FIG. 3 is an exemplary embodiment of the present invention and is just one of any number of configurations that may be implemented in semiconductor devices to dissipate heat therefrom.

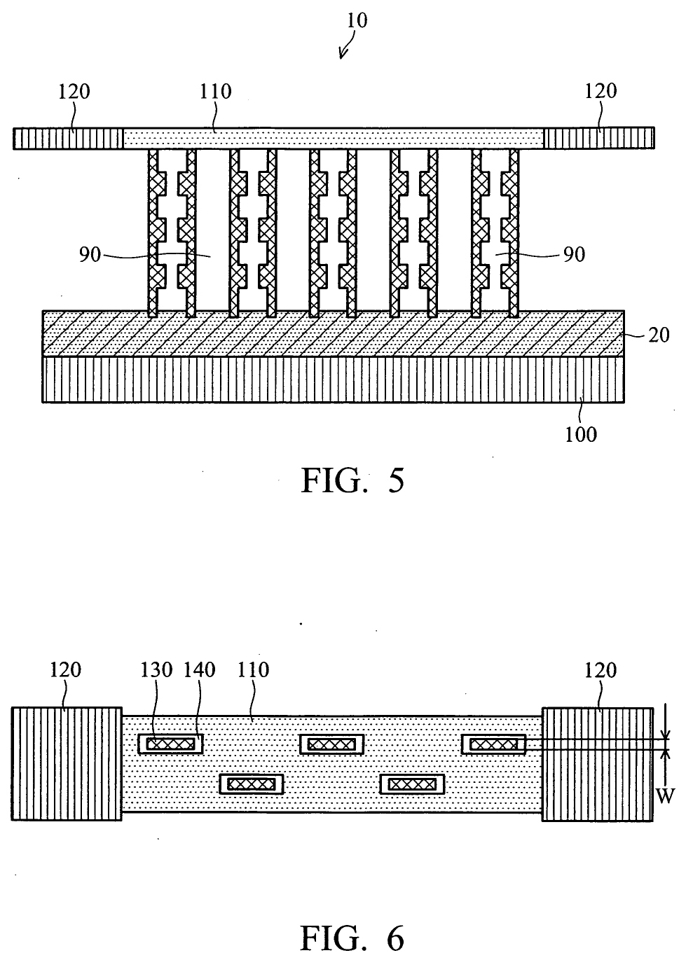

FIG. 5 shows a cross sectional view of a semiconductor structure for heat dissipation in a semiconductor device according to yet another embodiment of the present invention. A plurality of bridged via stacks 130 have one end in contact with substrate 20 and their top ends disposed in power line 110 so that bridged via stacks 130 may conduct heat generated by power line 110 into substrate 20 through bridged via stacks 130. It is understood that the top ends of bridged via stacks 130 are not in contact with power line 110 to avoid electrical shorts but that the top ends are instead substantially surrounded by dielectric films 140 for insulation from power line 110. Dielectric films 140 may include conventional insulating materials such as, for example silicon dioxide.

The bridged via stack structures 130 are shown in FIG. 5 are spaced apart alternatively from each other in power line 110. A top view of the semiconductor structure of FIG. 5 depicting the bridged via stack structures 130 alternatively spaced apart from each other in power line 110 is shown in FIG. 6. In one embodiment, a width W of bridged via stack structure 130 is from about 0.1 μm to about 10 μm, although this may be further reduced as process technology improves; and the distance that a bridged via stack structure 130 is spaced apart from another bridged via stack structure 130 is a width of one bridged via stack structure 130. In another embodiment, a ratio of the width of one of the bridged via stack structures 130 to power line 110 is between about 1 to about 20. It is understood by those skilled in the art that the placement and the number of bridged via stack structures 130 disposed in power line 110 as well as the dimensions of bridged via stack structures 130 are determined based upon the circuit pattern, the design rules for integrated circuit device being fabricated, and heat dissipation concerns for efficiently dissipating heat away from the semiconductor device. It is further understood that the dimensions of bridged via stack structures 130 may be limited by the device technology but that the dimensions may be further reduced as process technology improves.

In the preceding detailed description, the present invention for dissipating heat from a semiconductor device is described with reference to specifically exemplary embodiments thereof. It will, however, be evident that various modifications, changes or improvements that become apparent to persons of ordinary skill in the art after reading this disclosure may be made thereto without departing from the broader spirit and scope of the present invention, as set forth in the claims. The specification and drawings are, accordingly, to be regarded as illustrative and not restrictive. It is understood that the present invention is capable of using various other combinations and environments and is capable of changes or modifications within the scope of the inventive concept as expressed herein.

1-25. (canceled)

26. A semiconductor configuration for dissipating heat away from a semiconductor device having a plurality of power lines, the configuration comprising:
a semiconductor substrate; and
a plurality of interconnect structures disposed on the substrate and in contact therewith and extending through the semiconductor device, the interconnect structures for dissipating heat through the substrate,
wherein the plurality of interconnect structures are embedded into and isolated from a power line.

27. The semiconductor configuration of claim 26, further comprising a heat sink in contact with the substrate.

28. The semiconductor configuration of claim 26, wherein each of the plurality of interconnect structures comprises at least one via stack.

29. The semiconductor configuration of claim 28, wherein the plurality of interconnect structures are closed to the power line.

30. The semiconductor configuration of claim 28, wherein at least one of the plurality of interconnect structures is joined to one other of the plurality of interconnect structures using a bridge structure.

31. The semiconductor configuration of claim 28, including bridge structures, each of the bridge structures joins a respective one of the plurality of interconnect structures to one other of the plurality of interconnect structures.

32. The semiconductor configuration of claim 28, wherein a width of each of the interconnect structures is from about 0.1 μm to about 10 μm.

33. The semiconductor configuration of claim 28, wherein the interconnect structures are spaced apart from each other by a width of one of the interconnect structures.

34. The semiconductor configuration of claim 28, wherein each of the plurality of bridges is alternatively spaced apart from a serpentine power line by a distance.

35. The semiconductor configuration of claim 34, wherein the distance is a width of one of the plurality of interconnect structures.

36. The semiconductor configuration of claim 28, wherein each of the plurality of interconnect structures is spaced apart from a linear power line by a distance.

37. The semiconductor configuration of claim 36, wherein the distance is the width of one of the plurality of interconnect structures.

38. A semiconductor configuration for dissipating heat away from a semiconductor device having a plurality of power bus lines, comprising:
a semiconductor substrate; and
a plurality of interconnect structures, each of the interconnect structures having at least one via stack, the interconnect structures disposed on the substrate and in contact therewith and extending through the semiconductor device, the interconnect structures for dissipating heat through the substrate,
wherein the plurality of interconnect structures are alternatively spaced apart and embedded into a single serpentine power line by a distance.

39. A semiconductor configuration for dissipating heat away from a semiconductor device having a plurality of power lines, comprising:
a semiconductor substrate; and
a plurality of interconnect structures disposed on the substrate and in contact therewith and extending through the semiconductor device, the interconnect structures for dissipating heat through the substrate,
wherein the plurality of interconnect structures are embedded into and periodically spaced apart along a longitudinal axis of a serpentine power line by a distance.

40. A method for forming a semiconductor configuration for dissipating heat away from a semiconductor device having a plurality of power bus lines, comprising:
providing a semiconductor substrate; and
forming a plurality of interconnect structures disposed on the substrate and in contact therewith and extending through the semiconductor device, the interconnect structures for dissipating heat through the substrate,
wherein the plurality of interconnect structures are embedded into and isolated from a plurality of power bus lines.

41. The method of claim 40, further comprising providing a heat sink in contact with the substrate.
